(19) United States
(12) Patent Application Publication
(10) Pub. No.: US 2026/0157054 A1
(43) Pub. Date: Jun. 4, 2026

(54) DISPLAY PANEL AND ELECTRONIC APPARATUS INCLUDING THE SAME

(71) Applicant: Samsung Display Co., Ltd., Yongin-Si (KR)

(72) Inventors: Yeongwoo Kwon, Yongin-si (KR); Jinsu Byun, Yongin-si (KR); Yangho Jung, Yongin-si (KR); Gwangmin Cha, Yongin-si (KR)

(21) Appl. No.: 19/244,361

(22) Filed: Jun. 20, 2025

(30) Foreign Application Priority Data
Dec. 2, 2024 (KR) 10-2024-0176723

(51) Int. Cl. H10K 59/124; H10K 59/122; H10K 59/123; H10K 59/80; H10K 102/00

(52) U.S. Cl. CPC H10K 59/124; H10K 59/122; H10K 59/123; H10K 59/80515; H10K 2102/351

(57) ABSTRACT

A display panel and an electronic apparatus including the display panel includes a planarization layer, a plurality of convex portions disposed on the planarization layer and spaced apart from each other, wherein an upper surface of each of the plurality of convex portions includes a first convex surface, a convex insulating layer covering the plurality of convex portions and including an upper surface that includes a plurality of second convex surfaces corresponding to the plurality of convex portions, and a pixel electrode disposed on the convex insulating layer and including an upper surface that includes a plurality of third convex surfaces corresponding to the plurality of second convex surfaces.

### CROSS-REFERENCE TO RELATED APPLICATION

This application is based on and claims priority under 35 U.S.C. § 119 to Korean Patent Application No. 10-2024-0176723, filed on Dec. 2, 2024, in the Korean Intellectual Property Office, the disclosure of which is incorporated by reference herein in its entirety.

### BACKGROUND

### 1. Field

Aspects of the present disclosure relate to a display panel and an electronic apparatus including the same, and more particularly, to a display panel in which brightness reduction in a lateral direction is reduced and an electronic apparatus including the display panel.

### 2. Description of Related Art

Display panels have been used in various electronic apparatuses. For user convenience, it is necessary to increase not only visibility in a front direction but also visibility in a lateral direction.

### SUMMARY

However, in a display panel and an electronic apparatus including the same according to the related art, when the display panel and the electronic apparatus including the same are viewed from a lateral direction, brightness of displayed images is low, and visibility is poor.

One or more embodiments include a display panel in which brightness reduction in a lateral direction is reduced and an electronic apparatus including the display panel. However, such a technical objective is just an example, and the disclosure is not limited thereto.

Additional aspects will be set forth in part in the description which follows and, in part, will be apparent from the description, or may be learned by practice of the presented embodiments of the disclosure.

According to one or more embodiments, a display panel includes a planarization layer, a plurality of convex portions disposed on the planarization layer and spaced apart from each other. An upper surface of each of the plurality of convex portions includes a first convex surface, a convex insulating layer covering the plurality of convex portions. The upper surface further includes a plurality of second convex surfaces corresponding to the plurality of convex portions, and a pixel electrode disposed on the convex insulating layer including an upper surface that has a plurality of third convex surfaces corresponding to the plurality of second convex surfaces.

The plurality of convex portions may include an organic material.

The convex insulating layer may include an inorganic material.

The pixel electrode may extend outside of the convex insulating layer and be electrically connected to a thin-film transistor disposed below the planarization layer through a contact hole in the planarization layer.

The display panel may further include a pixel-defining layer including an opening around a central portion of the pixel electrode and disposed on the planarization layer to cover an edge of the pixel electrode.

In a plan view, the plurality of convex portions may be located in the opening.

In a plan view, some of the plurality of convex portions may be located outside the opening.

The display panel may further include a connector region located between the plurality of convex portions, connecting the plurality of convex portions to each other, and having a thickness less than a maximum height of each of the plurality of convex portions.

The plurality of convex portions and the connector regions may be integral as a single body.

A taper angle at an edge of each of the plurality of convex portions with respect to an upper surface of the planarization layer may be about 25° to about 35°.

In a plan view, each of the plurality of convex portions may have a circular shape.

A diameter of the circular shape may be about 2 μm to about 10 μm.

A thickness of the convex insulating layer may be about 0.5 μm to about 2 μm.

In a plan view, each of the plurality of convex portions may have a shape extending in one direction.

In a plan view, an area of each of the plurality of second convex surfaces may be greater than an area of the first convex surface.

According to one or more embodiments, an electronic apparatus includes a processor, and a display panel controlled by the processor, wherein the display panel includes a planarization layer, a plurality of convex portions disposed on the planarization layer and spaced apart from each other, wherein an upper surface of each of the plurality of convex portions includes a first convex surface, a convex insulating layer covering the plurality of convex portions and including an upper surface that includes a plurality of second convex surfaces corresponding to the plurality of convex portions, and a pixel electrode disposed on the convex insulating layer and including an upper surface that includes a plurality of third convex surfaces corresponding to the plurality of second convex surfaces.

The plurality of convex portions may include an organic material.

The convex insulating layer may include an inorganic material.

The display panel may further include a pixel-defining layer including an opening around a central portion of the pixel electrode and disposed on the planarization layer to cover an edge of the pixel electrode.

In a plan view, the plurality of convex portions may be located in the opening.

The display panel may further include a connector region located between the plurality of convex portions, connecting the plurality of convex portions to each other, and having a thickness less than a maximum height of each of the plurality of convex portions.

The plurality of convex portions and the connector region may be integral as a single body.

A taper angle at an edge of each of the plurality of convex portions with respect to an upper surface of the planarization layer may be about 25° to about 35°.

In a plan view, an area of each of the plurality of second convex surfaces may be greater than an area of the first convex surface.

Other aspects, features, and advantages will be apparent from specific descriptions, claims, and drawings to carry out the disclosure below.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of an electronic apparatus according to an embodiment;

FIG. 2 is a schematic view of electronic apparatuses according to aspects of the present disclosure;

FIG. 3 is a schematic view showing examples of wearable electronic apparatuses as electronic apparatuses according to aspects of the present disclosure;

FIG. 4 is a schematic view showing examples of vehicle electronic apparatuses as electronic apparatuses according to aspects of the present disclosure;

FIG. 5 is a schematic plan view of a display panel according to aspects of the present disclosure;

FIG. 6 is a schematic side view of the display panel of FIG. 5 according to aspects of the present disclosure;

FIG. 7 is a schematic cross-sectional view of the display panel of FIG. 5 taken along line A-A′ of FIG. 5 according to aspects of the present disclosure;

FIG. 8 is a schematic cross-sectional view of a display panel according to aspects of the present disclosure;

FIG. 9 is a schematic cross-sectional view of a display panel according to aspects of the present disclosure;

FIG. 10 is a schematic cross-sectional view of a display panel according to aspects of the present disclosure;

FIG. 11 is a schematic plan view of a portion of a display panel according to aspects of the present disclosure;

FIG. 12 is a schematic plan view of a portion of a display panel according to aspects of the present disclosure;

FIG. 13 is a schematic cross-sectional view of a portion of a display panel according to aspects of the present disclosure; and

FIGS. 14 to 17 are schematic cross-sectional views showing operations of manufacturing a display panel according to aspects of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, and c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below with reference to the drawings. However, the disclosure is not limited to embodiments described below and may be implemented in various forms.

Hereinafter, embodiments will be described with reference to the accompanying drawings, wherein like reference numerals refer to like elements throughout and a repeated description thereof is omitted.

As used herein, when various elements such as a layer, a region, a plate, and the like are disposed “on” another element, not only the elements may be disposed “directly on” the other element, but another element may be disposed therebetween. In addition, for convenience of description, in the drawings, the sizes of elements may be exaggerated or reduced. As an example, the size and thickness of each element shown in the drawings are arbitrarily represented for convenience of description, and thus, the disclosure is not necessarily limited thereto.

In the embodiments below, x axis, y axis and z axis are not limited to three axes of the rectangular coordinate system, and may be interpreted in a broader sense. For example, x axis, y axis, and z axis may be perpendicular to one another, or may represent different orientations that are not perpendicular to one another.

While such terms as “first” and “second” may be used to describe various components, such components must not be limited to the above terms. The above terms are used to distinguish one component from another.

It will be understood that the terms “comprise,” “comprising,” “include” and/or “including” as used herein specify the presence of stated features or components but do not preclude the addition of one or more other features or components.

In the present specification, “A and/or B” means A or B, or A and B. In the present specification, “at least one of A and B” means A or B, or A and B.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. As an example, in the present specification, it will be understood that when a layer, region, or element is referred to as being “electrically connected” to another layer, region, or element, it may be “directly electrically connected” to the other layer, region, or element or may be “indirectly electrically connected” to other layer, region, or element t with other layer, region, or element interposed therebetween.

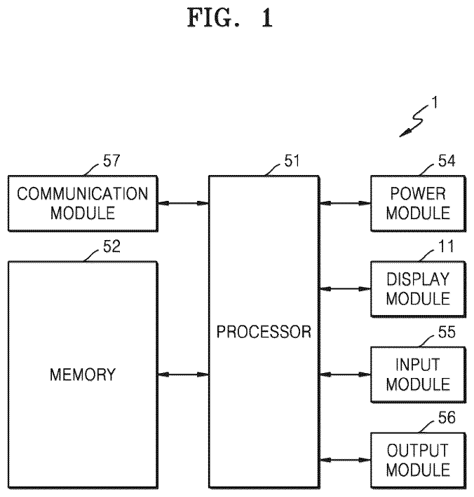

FIG. 1 is a schematic block diagram of an electronic apparatus 1 according to aspects of the present disclosure. The electronic apparatus 1 according to an embodiment may be a display apparatus or may further include, in addition to a display module 11, one or more other modules and the like having a different function than the display module 11.

As shown in FIG. 1, the electronic apparatus 1 according to an embodiment may include the display module 11, one or more processors 51, a memory 52, a power module 54, an input module 55, an output module 56, and a communication module 57.

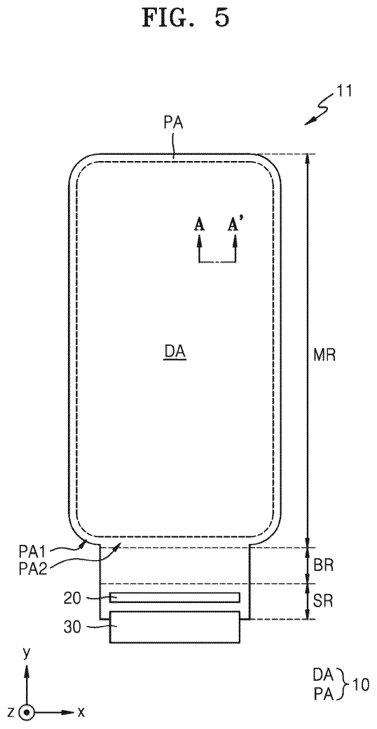

The display module 11 may include a display panel 10 (see FIG. 5) as described below. As an example, the display module 11 may include the display panel 10, a data driver 20 mounted thereon, and the like. The display panel 10 is described below.

The one or more processors 51 may control most of elements of the electronic apparatus 1 individually, as a collective or as a selection of the one or more processors. As an example, a processor or multiple processors of the one or more processors 51 may output digital video data to the display module 11 such that the display module 11 displays images, and may receive input data from the input module 55 to allow a function corresponding to the relevant data to be performed by the electronic apparatus 1. The one or more processors 51 may include at least one of a central processing unit (CPU), an application processor (AP), a graphic processing unit (GPU), a communication processor (CP), an image signal processor (ISP), and a controller.

When needed, the processors of the one or more processors 51 may be divided into two or more portions in a functional or structural viewpoint. As an example, the processor 51 may include a main processor in the form of a first driving chip including a central processing unit, and an auxiliary processor in the form of a second driving chip, which is a portion of the display module 11. The auxiliary processor in the form of the second driving chip may include a controller receiving image signals from the main processor and processing image signals to match interface specifications of the display panel 10 included in the display module 11.

The memory 52 may include at least one of a non-volatile memory and a volatile memory. The memory 52 may store data information required for operations of the processor 51 or the display module 11. When one or more processors 51 execute an application stored in the memory 52, data signals for images and/or an input control signal may be transferred to the display module 11, and the display module 11 may process provided signals and output image information.

The power module 54 may include a power supply module such as a power adapter or a battery unit, and a power converting module converting power supplied by the power supply module and generating power required for operations of the electronic apparatus 1. Power conversion by the power converting module may include DC-DC conversion, AC-DC conversion, and DC-AC conversion. However, the disclosure is not limited thereto.

The input module 55 may provide input information to the one or more processors 51 and/or the display module 11. The input module 55 may include not only a physical button, a keyboard, and a microphone, but also various kinds of sensor modules. Examples of the sensor module may include a touch sensor, a pressure sensor, a distance sensor, a position sensor, a digitizer, a motion recognition sensor, a camera sensor, a light reception sensor, a photoelectric conversion sensor, and/or a temperature sensor. In addition, the sensor module may include biometric sensors such as a blood pressure sensor, a blood sugar sensor, an electrocardiogram sensor, and/or a heart rate sensor.

The output module 56 may receive information other than images received from the one or more processors 51 and may provide the information to a user. The output module 56 may include, for example, a sound module, a haptic module, and/or a light-emitting module. In addition, the output module 56 may include a unique functional module of the electronic apparatus 1 such as a cooling module of a refrigerator.

For reference, the display module 11 may be also in charge of an output function. As an example, the display panel 10 included in the display module 11 may display (output) information processed by the electronic apparatus 1. As an example, the display panel 10 may display execution screen information of an application driven by the electronic apparatus 1, a user interface (UI), or graphic user interface (GUI) information corresponding to the execution screen information. The display panel 10 may include a display layer and a touchscreen layer, wherein the display layer displays images, and the touchscreen layer senses a user's touch input. Accordingly, the display panel 10 may serve as a portion of the input module 55 that provides an input interface between the electronic apparatus 1 and a user, and simultaneously, serves as a portion of the output module 56 that provides an output interface between the electronic apparatus 1 and a user.

The communication module 57 is a module responsible for transmission/reception of information between the electronic apparatus 1 and an external apparatus, and may include a receiver and a transmitter. The communication module 57 may include various kinds of wireless communication modules such as a mobile communication module, a broadcasting reception module, a wireless Internet module, a short-range communication module, a Wi-Fi module, and/or a Bluetooth module, or various kinds of wired communication modules.

The electronic apparatus 1 shown in FIG. 1 is just an example. As an example, a display apparatus not having a communication function may not include the communication module 57. In addition, in the case where the electronic apparatus 1 includes a display apparatus, at least one element of the electronic apparatus 1 may be included in the display apparatus. In addition, some of individual modules functionally included in one module may be included in the display apparatus, and other some may be included in the electronic apparatus 1 separately from the display apparatus. As an example, the display apparatus may include the display module 11, and the processor 51, the memory 52, and the power module 54 may be elements of the electronic apparatus 1, not the display apparatus. Alternatively, the display apparatus may include the display module 11 and the power module 54, and the power module 54 may supply power to the elements such as the processor 51 and the memory 52 of the electronic apparatus 1. However, various modifications may be made.

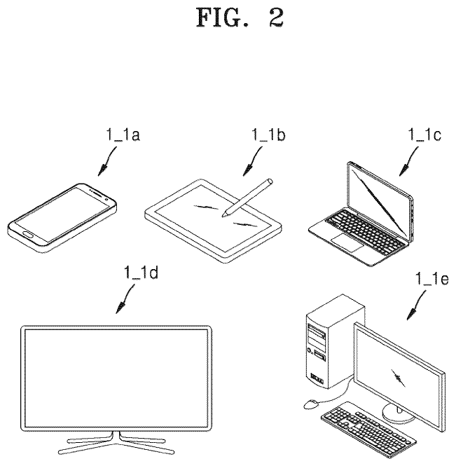

FIG. 2 is a schematic view of the electronic apparatuses 1 according to embodiments. FIG. 2 shows, an example of the electronic apparatus 1, a smartphone 1_1a, a tablet personal computer (PC) 1_1b, a laptop 1_1c, and a TV 1_1d, and a desk monitor 1_1e.

The smartphone 1_1a may include not only the processor 51, the memory 52, the power module 54, and the display module 11, but also the input module 55 such as a touch sensor, and the communication module 57. The smartphone 1_1a may process information received through the communication module 57 or other input modules and display the information through the display module 11.

Similar to the smartphone 1_1a, the tablet personal computer (PC) 1_1b, the laptop 1_1c, the TV 1_1d, and/or the desk monitor 1_1e may include the display module 11 and the input module 55 and may include the communication module 57 depending on a case.

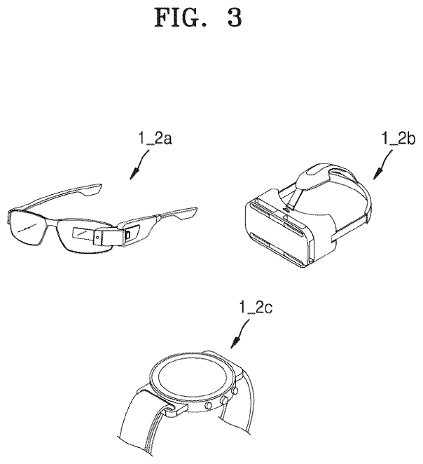

FIG. 3 is a schematic view showing a case where electronic apparatuses 1 according to embodiments are wearable electronic apparatuses. FIG. 3 shows, as an example of the electronic apparatus 1, smart glasses 1_2a, a head mount display 1_2b, and a smartwatch 1_2c.

The smart glasses 1_2a and the head mount display 1_2b may include the display module 11 displaying images and a reflector including a display surface displaying images to reflect the images and providing the images to a user's eyes. A user may experience virtual reality or augmented reality using the electronic apparatus 1.

The smartwatch 1_2c may include a biometric sensor as the input module 55 and provide, through the display module 11, a user with bio information recognized through the biometric sensor.

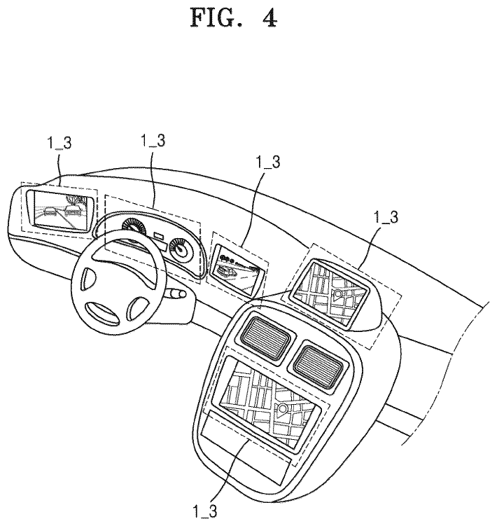

FIG. 4 is a schematic view showing a case where the electronic apparatus 1 according to embodiments are a vehicle electronic apparatus 1_3. As shown in FIG. 4, the vehicle electronic apparatus 1_3 may be included in an instrument board, a center facia, or the like of an automobile, or may be a center information display (CID) disposed on a dashboard of an automobile or a room mirror display replacing a side mirror.

However, the electronic apparatus 1 according to an embodiment is not limited thereto. As an example, the electronic apparatus 1 according to an embodiment may include not only apparatuses centered on displays such as billboards, electronic boards, and/or game consoles, but also various home appliances that display information through a display module 11, such as a refrigerator, a washing machine, a dryer, an air conditioner, and/or a robot vacuum cleaner. In addition, in the case where the display module 11 has a function of transmitting light, the electronic apparatus 1 may be a smart window or a transparent display apparatus displaying a background and display images together. However, the electronic apparatus 1 according to the disclosure is not limited thereto. As long as the electronic apparatus 1 includes the display panel 10 described below, any electronic apparatus may fall within the scope of the disclosure.

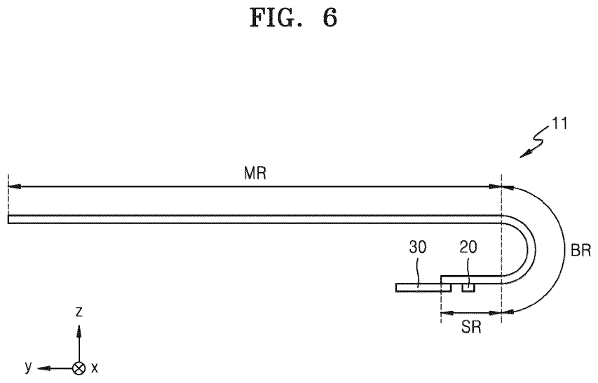

FIG. 5 is a schematic plan view of the display module 11 including the display panel 10 according to an embodiment, and FIG. 6 is a schematic side view of the display module 11 of FIG. 5. The display module 11 included in the electronic apparatus 1 may include the display panel 10 as shown in FIGS. 5 and 6. This is also applicable to embodiments below and modifications thereof.

The display panel 10 may be shown to have a roughly rectangular shape in a plan view. As an example, as shown in FIG. 5, the display panel 10 may have a roughly rectangular shape having short sides in an x axis direction and long sides in a y axis direction in an xy-plane. In this case, an edge where a short side in the x axis direction meets a long side in the y axis direction may form a right angle or have a round shape with a preset curvature. In a plan view, the shape of the display panel 10 is not limited to a rectangle, and may include other polygonal, elliptical, or irregular shapes.

The display panel 10 may include a display area DA and a peripheral area PA outside the display area DA. The display area DA is a region in which images are displayed, and a plurality of pixels may be located in the display area DA. The display area DA may have various shapes, for example, circular shapes, elliptical shapes, polygonal shapes, or shapes of specific figures. It is shown in FIG. 5 that the display area DA has a roughly rectangular shape having round corners.

The peripheral area PA may be located outside the display area DA. The peripheral area PA may include a first peripheral area PA1 and a second peripheral area PA2, wherein the first peripheral area PA1 is located to surround at least a portion of the display area DA, and the second peripheral area PA2 is located at the lower end of the display area DA and extends in a first direction (e.g., x axis direction). The width of the second peripheral area PA2 in the first direction (e.g., x axis direction) may be less than the width of the display area DA. At least a portion of the second peripheral area PA2 may be easy to bend through this structure.

A planar shape of the display panel 10 shown in FIG. 5 may be substantially equal to the shape of a substrate 100 included in the display panel 10. When the display panel 10 includes the display area DA and the peripheral area PA outside the display area DA, it may represent the substrate 100 includes the display area DA and the peripheral area PA outside the display area DA. Hereinafter, for convenience, description is made on the assumption that the substrate 100 includes the display area DA and the peripheral area PA.

The display panel 10 may include a main region MR, a bent region BR outside the main region MR, and a sub-region SR apart from the main region MR with the bent region BR between the sub-region SR and the main region MR. The main region MR may be located on one side of the bent region BR, and the sub-region SR may be located on the other side of the bent region BR. As shown in FIG. 6, the display panel 10 may be bent in the bent region BR, and when viewed from a third direction (e.g., z-axis direction), at least portion of the sub-region SR may overlap the main region MR.

Although it is shown in FIG. 6 that the display panel 10 is bent, the disclosure is not limited thereto. As an example, the display panel 10 may be a foldable display panel, and in this case, the display panel 10 may be bent inside the display area DA around a bending axis crossing the display area DA. When needed, the display panel 10 may not be bent. The sub-region SR may be a non-display area.

As described above, the display panel 10 may be a rigid display panel that has rigidity and thus is not easily bent, or a flexible display panel that is flexible and thus is easily bendable, foldable, or rollable. As an example, the display panel 10 may include a foldable display panel that is foldable and unfoldable, a curved display panel that has a curved display surface, a bended display panel in which a region except a display surface is bent, a rollable display panel that is rollable and unrollable, and a stretchable display panel that is stretchable.

The display module 11, including the display panel 10 may include a data driver 20 mounted in the sub-region SR of the display panel 10. The data driver 20 may be disposed on the display panel 10 in the form of an integrated circuit (IC). As an example, the data driver 20 may be a data driving integrated circuit generating data signals. The data driver 20 may be the auxiliary processor in the form of the second driving chip as described above and may be a portion of the processor 51 (see FIG. 1).

A display circuit board 30 may be attached to the end of the sub-region SR of the display panel 10. That is, when needed, the display module 11 may include the display circuit board 30. The display circuit board 30 may be electrically connected to the data driver 20 or the like through a pad of the sub-region SR of the display panel 10.

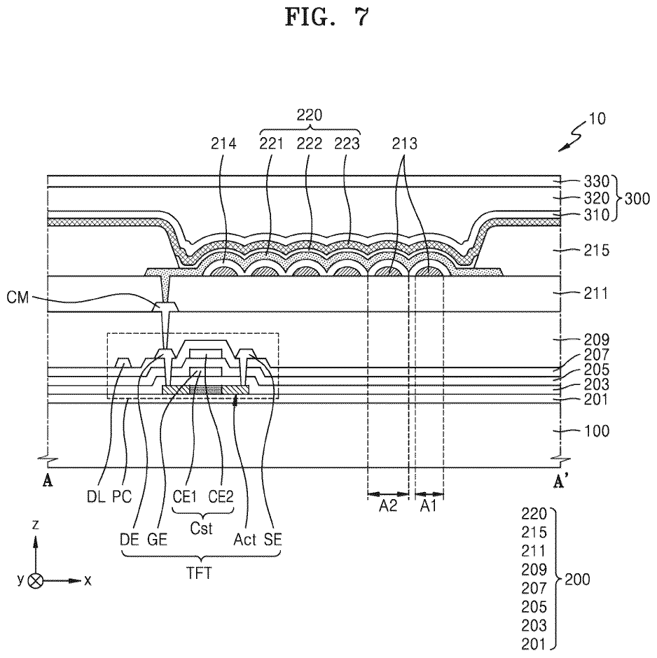

FIG. 7 is a schematic cross-sectional view of the display panel 10 of FIG. 5, taken along line A-A′ of FIG. 5. Referring to FIG. 7, the display panel 10 may include the substrate 100. Various elements forming the display panel 10 may be disposed on the substrate 100. As an example, a display layer 200 and a thin-film encapsulation layer 300 may be disposed on the substrate 100.

The substrate 100 may include glass, ceramic, metal, or polymer resin. The substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure having two layers or more including the above-described polymer resin, and an inorganic material layer disposed between the polymer resin layers. Alternatively, the substrate 100 may have a structure in which a layer including the polymer resin and an inorganic material layer are alternately stacked. The inorganic material layer may include, for example, silicon oxide, silicon nitride or silicon oxynitride, and may have a single-layered structure or a multi-layered structure. The inorganic material layer may serve as a barrier layer preventing penetration of an external foreign substance.

The display layer 200 may include a plurality of pixels. The display layer 200 may include a display element 220 located for each pixel, a pixel circuit located for each pixel, and insulating layers. The pixel circuit may include a thin-film transistor TFT and a storage capacitor Cst. The display element 220 may include, for example, an organic light-emitting diode OLED.

The thin-film encapsulation layer 300 may cover the display layer 200. The thin-film encapsulation layer 300 may include at least one inorganic encapsulation layer and at least one organic encapsulation layer. The thin-film encapsulation layer 300 may prevent or reduce impurities such as moisture from the outside from penetrating the display elements.

Hereinafter, the display layer 200, the thin-film encapsulation layer 300, and the like are specifically described.

A buffer layer 201 may be formed on the substrate 100, wherein the buffer layer 201 is configured to prevent impurities from penetrating a semiconductor layer Act of the thin-film transistor TFT. The buffer layer 201 may include an inorganic insulating material such as silicon nitride, silicon oxynitride, and/or silicon oxide, and include a single-layered structure or a multi-layered structure.

A pixel circuit PC may be disposed on the buffer layer 201. The pixel circuit PC may include the thin-film transistor TFT and the storage capacitor Cst. The thin-film transistor TFT may include the semiconductor layer Act, a gate electrode GE, a source electrode SE, and/or a drain electrode DE. The thin-film transistor TFT shown in FIG. 7 may be a driving transistor. When an emission control transistor and the like are disposed between the driving transistor and the organic light-emitting diode OLED, in this case, unlike FIG. 7, the thin-film transistor TFT, which is the driving transistor, may not be connected to a pixel electrode 221 of the organic light-emitting diode through a contact metal layer CM and may be electrically connected to the emission control transistor (not shown), and the emission control transistor may be electrically connected to the pixel electrode 221 of the organic light-emitting diode. When needed, the thin-film transistor TFT shown in FIG. 7 may be regarded as the emission control transistor. Hereinafter, for convenience, a structure in which the thin-film transistor TFT of FIG. 7 is connected to the pixel electrode 221 of the organic light-emitting diode through the contact metal layer CM is described.

A data line DL of the pixel circuit PC may be electrically connected to a switching transistor included in the pixel circuit PC although not shown in FIG. 7.

The semiconductor layer Act may include polycrystalline silicon. Alternatively, the semiconductor layer Act may include amorphous silicon, an oxide semiconductor, or an organic semiconductor. The gate electrode GE may include a low-resistance metal material. As an example, the gate electrode GE may include conductive materials including molybdenum (Mo), aluminum (Al), copper (Cu), and/or titanium (Ti), and the like and have a multi-layered structure or a single-layered structure. As an example, the gate electrode GE may have a three-layered structure of a molybdenum layer, an aluminum layer, and a molybdenum layer (Mo/Al/Mo).

The gate insulating layer 203 between the semiconductor layer Act and the gate electrode GE may include an inorganic insulating material including silicon oxide, silicon nitride, silicon oxynitride, aluminum oxide, titanium oxide, tantalum oxide, and/or hafnium oxide and the like. A gate insulating layer 203 may have a single-layered structure or a multi-layered structure.

The source electrode SE and the drain electrode DE may be disposed on the same layer as the data line DL and may include the same material as a material of the data line DL. The source electrode SE, the drain electrode DE, and the data line DL may include a material having a high conductivity. The source electrode SE and the drain electrode DE may include conductive materials including molybdenum (Mo), aluminum (Al), copper (Cu), titanium (Ti), and the like and have a multi-layered structure or a single-layered structure. As an example, the source electrode SE, the drain electrode DE, and the data line DL may have a multi-layered structure of a titanium layer, an aluminum layer, and a titanium layer (Ti/Al/Ti).

Although it is shown in FIG. 7 that the thin-film transistor TFT includes both the source electrode SE and the drain electrode DE, the disclosure is not limited thereto. As an example, a drain region of the semiconductor layer Act of the thin-film transistor TFT may be integrally formed with a source region of a semiconductor layer of another thin-film transistor. In this case, the thin-film transistor TFT may not have the drain electrode DE, and the other thin-film transistor may not have a source electrode. In this case, it may be shown in a circuit diagram that a drain of the thin-film transistor TFT is connected to a source of another thin-film transistor. As an example, when a drain of the driving transistor is connected to a source of the emission control transistor, the driving transistor may not have a drain electrode, the emission control transistor may not have a source electrode, and a drain region of a semiconductor layer of the driving transistor may be integrally formed with a source region of the emission control transistor. Similarly, when a source of the driving transistor is connected to a drain of an operation control transistor, the driving transistor may not have a source electrode, the operation control transistor may not have a drain electrode, and a source region of a semiconductor layer of the driving transistor may be integrally formed with a drain region of the operation control transistor. Accordingly, the driving transistor may consequently not have both a source electrode and a drain electrode.

The storage capacitor Cst may include a lower electrode CE1 and an upper electrode CE2 overlapping each other with a first interlayer insulating layer 205 between the upper electrode CE2 and the lower electrode CE1. The storage capacitor Cst may overlap the thin-film transistor TFT. It is shown in FIG. 7 that the gate electrode GE of the thin-film transistor TFT serves as the lower electrode CE1 of the storage capacitor Cst. However, the disclosure is not limited thereto, and the storage capacitor Cst may not overlap the thin-film transistor TFT. The storage capacitor Cst may be covered by a second interlayer insulating layer 207. The upper electrode CE2 of the storage capacitor Cst may include conductive materials including molybdenum (Mo), aluminum (Al), copper (Cu), and/or titanium (Ti), and the like and have a multi-layered structure or a single-layered structure.

The first interlayer insulating layer 205 and the second interlayer insulating layer 207 may each include an inorganic insulating material including silicon oxide, silicon nitride, silicon oxynitride, aluminum oxide, titanium oxide, tantalum oxide, and/or hafnium oxide and the like. The first interlayer insulating layer 205 and the second interlayer insulating layer 207 may have a single-layered structure or a multi-layered structure.

The pixel circuit PC including the thin-film transistor TFT and the storage capacitor Cst may be covered by a first organic insulating layer 209.

The pixel circuit PC may be electrically connected to the pixel electrode 221. As an example, as shown in FIG. 7, the contact metal layer CM may be disposed between the thin-film transistor TFT and the pixel electrode 221. The contact metal layer CM may be connected to the thin-film transistor TFT through a contact hole formed in the first organic insulating layer 209, and the pixel electrode 221 may be connected to the contact metal layer CM through a contact hole formed in the second organic insulating layer 211 disposed on the first organic insulating layer 209 to cover the contact metal layer CM and the like. The contact metal layer CM may include conductive materials including molybdenum (Mo), aluminum (Al), copper (Cu), and/or titanium (Ti), and the like and have a multi-layered structure or a single-layered structure. As an example, the contact metal layer CM may have a multi-layered structure of a titanium layer, an aluminum layer, and a titanium layer (Ti/Al/Ti).

The first organic insulating layer 209 and the second organic insulating layer 211 may include an organic insulating material such as acryl, polystyrene (PS), polymethylmethacrylate (PMMA), benzocyclobutene (BCB), polyimide, or hexamethyldisiloxane (HMDSO) or similar. As an example, the first organic insulating layer 209 and the second organic insulating layer 211 may each include polyimide. The first organic insulating layer 209 and/or the second organic insulating layer 211 may have a substantially flat upper surface. That is, the second organic insulating layer 211 may be a planarization layer.

A plurality of convex portions 213 may be disposed on the second organic insulating layer 211. The plurality of convex portions 213 may be spaced apart from each other. An upper surface of each of the plurality of convex portions 213 may include a convex surface. The convex surface included in the upper surface of each of the plurality of convex portions 213 may be referred to as a first convex surface.

The plurality of convex portions 213 may include an organic insulating material such as acryl, polystyrene (PS), polymethylmethacrylate (PMMA), benzocyclobutene (BCB), polyimide, hexamethyldisiloxane (HMDSO), or similar. During the manufacturing process, the plurality of convex portions 213 shown in FIG. 7 may be formed by forming a base organic insulating layer including the organic insulating material on the second organic insulating layer 211, and patterning the base organic insulating layer using a photoresist and the like with an etchant selected for the organic insulating material followed by removal of the photoresist. Because the base organic insulating layer includes the organic insulating material, during the patterning process, the upper surface of each of the plurality of convex portions 213 may include a convex surface similar to the surface shape of a convex lens as shown in FIG. 7. When needed, the plurality of convex portions 213 may be formed through inkjet printing and the like. Even in this case, the upper surface of each of the plurality of convex portions 213 may include a convex surface similar to the surface shape of a convex lens as shown in FIG. 7.

The plurality of convex portions 213 may be covered by a convex insulating layer 214. The convex insulating layer 214 may include an inorganic insulating material. As an example, the convex insulating layer 214 may include an inorganic insulating material including silicon oxide, silicon nitride, silicon oxynitride, aluminum oxide, titanium oxide, tantalum oxide, and/or hafnium oxide and the like. The convex insulating layer 214 including the inorganic insulating material may be formed through a deposition process such as chemical vapor deposition (CVD) and the like. Because the convex insulating layer 214 including the inorganic insulating material is formed in accordance with the shape of the upper surface of structures disposed thereunder, the upper surface of the convex insulating layer 214 may include a plurality of second convex surfaces corresponding to the plurality of convex portions 213 as shown in FIG. 7.

As shown in FIG. 7, an area A2 of each of the plurality of second convex surfaces may be greater than an area A1 of the first convex surface. This is because, while the convex insulating layer 214 is formed in accordance with the shape of the upper surface of the structures disposed thereunder, the convex insulating layer 214 fills spaces between the plurality of convex portions 213 disposed under the convex insulating layer 214. The convex insulating layer 214 fills the spaces between the plurality of convex portions 213, but an entire portion of the convex insulating layer 214 corresponding to the entire space between the plurality of convex portions 213 does not become flat. This is because the convex insulating layer 214 is formed in accordance with the shape of the upper surface of the structures disposed thereunder while having a roughly constant thickness. As a result, the area A2 (in a plan view) of each of the plurality of second convex surfaces included in the upper surface of the convex insulating layer 214 may be greater than the area A1 (in a plan view) of the first convex surface of a corresponding one of the plurality of convex portions 213.

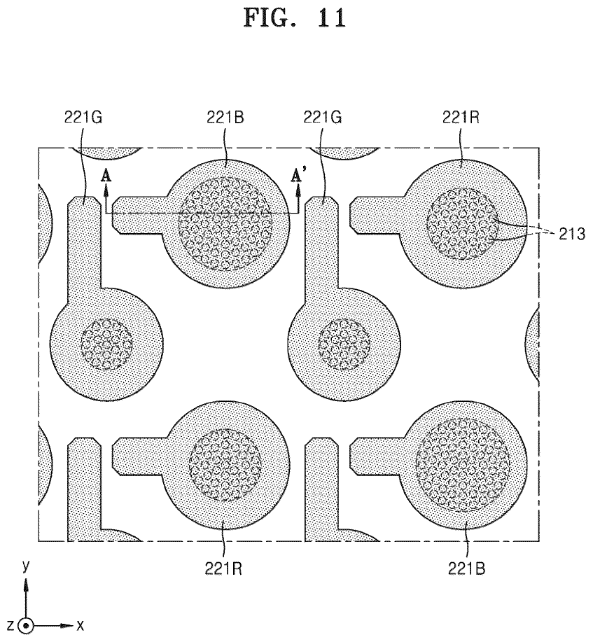

Unlike FIG. 7, which is a cross-sectional view, each of the plurality of convex portions 213 may be shown to have a circular shape in a plan view. This is as described below with reference to FIG. 11. Accordingly, each of the first convex surfaces of the plurality of convex portions 213 is shown to have a circular shape in a plan view. In this case, the area A1 of the first convex surface in a plan view may be calculated using a first diameter, which is a diameter of a lower surface of the convex portion 213. Each of the plurality of second convex surfaces included in the upper surface of the convex insulating layer 214 is also shown to have a circular shape in a plan view. In this case, the area A2 of the first convex surface in a plan view may be determined using a second diameter, which is a sum of the first diameter and twice the thickness of the convex insulating layer 214.

Table 1, printed below, shows how the first area A1, the second area A2, and a ratio of the second area A2 to the first area A1 change when the first diameter and the thickness of the convex insulating layer 214 change. In Table below, a ‘thickness’ denotes a thickness of the convex insulating layer 214. Each of the first area A1 and the second area A2 is rounded to a first decimal place.

TABLE 1

| | First | | | second | | |
|---|---|---|---|---|---|---|
| | diameter | A1 | thickness | diameter | A2 | A2/A1 |
| | (μm) | (μm²) | (μm) | (μm) | (μm²) | (%) |
| Example 1 | 2 | 3 | 0.5 | 3 | 7 | 233 |
| Example 2 | 3 | 7 | 0.5 | 4 | 13 | 186 |
| Example 3 | 4 | 13 | 0.5 | 5 | 20 | 154 |
| Example 4 | 5 | 20 | 0.5 | 6 | 28 | 140 |
| Example 5 | 8 | 50 | 0.5 | 9 | 64 | 128 |
| Example 6 | 10 | 79 | 0.5 | 11 | 95 | 120 |
| Example 7 | 2 | 3 | 1 | 4 | 13 | 433 |
| Example 8 | 3 | 7 | 1 | 5 | 20 | 286 |
| Example 9 | 4 | 13 | 1 | 6 | 28 | 215 |
| Example 10 | 5 | 20 | 1 | 7 | 38 | 190 |
| Example 11 | 8 | 50 | 1 | 10 | 79 | 158 |
| Example 12 | 10 | 79 | 1 | 12 | 113 | 143 |
| Example 13 | 2 | 3 | 2 | 6 | 28 | 933 |
| Example 14 | 3 | 7 | 2 | 7 | 38 | 543 |
| Example 15 | 4 | 13 | 2 | 8 | 50 | 385 |
| Example 16 | 5 | 20 | 2 | 9 | 64 | 320 |

In case of the plurality of convex portions 213 formed by patterning the base organic insulating layer using a photoresist and the like, a lower limit of the first diameter may be about 2 μm due to a resolution limit during an exposure process that uses the photoresist. In addition, when the first diameter is greater than 10 μm, it is impossible to maintain the shape of a sloped surface of each of the plurality of convex portions 213. As an example, the first diameter is greater than 10 μm, each of the plurality of convex portions 213 may become a shape having a flat upper surface instead of the shape such as a convex lens. Accordingly, as described in Table above, the first diameter may be about 2 μm to about 10 μm.

Because the convex insulating layer 214 may be formed through CVD as described above, the upper limit of the thickness of the convex insulating layer 214 may be about 2 μm as described in Table above by taking into account the characteristics and limit of the CVD when forming an inorganic insulating layer. In addition, when the thickness of the convex insulating layer 214 becomes less than 0.5 μm, a ratio of the second area A2 to the first area A1 becomes less than 120% as shown in Example 6 of Table above. When a ratio of the second area A2 to the first area A1 becomes less than 120%, an interval between the plurality of second convex surfaces included in the upper surface of the convex insulating layer 214 increases and a light efficiency thereof may deteriorate. Accordingly, the thickness of the convex insulating layer 214 may be about 0.5 μm to about 2 μm.

As shown in Table above, when the thickness of the convex insulating layer 214 is about 0.5 μm, a ratio of the second area A2 to the first area A1 is from about 120% to about 233%. When the thickness of the convex insulating layer 214 is about 1 μm, a ratio of the second area A2 to the first area A1 is from about 143% to about 433%. When the thickness of the convex insulating layer 214 is about 2 μm, a ratio of the second area A2 to the first area A1 is from about 320% to about 933%. Through this, the light efficiency of the display panel 10 and the electronic apparatus 1 including the same may be remarkably increased.

The pixel electrode 221 disposed on the second organic insulating layer 211, which is a planarization layer, may be disposed on the convex insulating layer 214. The pixel electrode 221 may be a reflective electrode. As an example, the pixel electrode 221 may include a reflective layer and a transparent or semi-transparent electrode layer disposed on the reflective layer, wherein the reflective layer includes Ag, Mg, Al, Pt, Pd, Au, Ni, Nd, Ir, Cr, or compound thereof. The transparent or semi-transparent electrode layer may include at least one of indium tin oxide (ITO), indium zinc oxide (IZO), zinc oxide (ZnO_{X}: ZnO or ZnO₂), indium oxide (In₂O₃), indium gallium oxide (IGO), or aluminum zinc oxide (AZO). As an example, the pixel electrode 221 may have a three-layered structure of ITO/Ag/ITO. The pixel electrode 221 may be shown to have an isolated shape in a plan view. The pixel electrode 221 may extend to the outside of the convex insulating layer 214, be connected to the contact metal layer CM under the second organic insulating layer 211 through a contact hole formed in the second organic insulating layer 211, and thus be electrically connected to the thin-film transistor TFT and the like.

Each of layers included in the pixel electrode 221, for example and without limitation, each of an ITO layer and an Ag layer may be formed by a physical deposition method such sputtering. The ITO layer, the Ag layer, or the like formed by sputtering may conform to the shape of the upper surface of the structures disposed thereunder. As described above, the upper surface of the convex insulating layer 214 includes the plurality of second convex surfaces which correspond to the plurality of convex portions 213. Accordingly, the upper surface of the pixel electrode 221 disposed on the convex insulating layer 214 may also include a plurality of third convex surfaces which correspond to the plurality of second convex surfaces.

A pixel-defining layer 215 may be disposed on the second organic insulating layer 211, which is a planarization layer. The pixel-defining layer 215 may prevent arcs and the like from occurring at an edge of the pixel electrode 221 by covering the edge of the pixel electrode 221 and increasing a distance between the pixel electrode 221 and a common electrode 223 over pixel electrode 221. That is, the pixel-defining layer 215 may expose the central portion of the pixel electrode 221 by having an opening around the central portion. The pixel-defining layer 215 may include an organic insulating material such as polyimide, an acrylic resin, benzocyclobutene, a phenolic resin, and the like and be formed by using a coating method such as spin coating and the like. Alternatively, the pixel-defining layer 215 may include an inorganic insulating material such as silicon nitride (SiNₓ), silicon oxynitride (SiON), silicon oxide (SiOₓ), or similar.

An intermediate layer 222 disposed between the pixel electrode 221 and the common electrode 223 may include an emission layer. The intermediate layer 222 may include a first functional layer disposed between the emission layer and the pixel electrode 221, and may include a second functional layer disposed between the emission layer and the common electrode 223. The emission layer may include a polymer organic material or a low-molecular weight organic material emitting light having a preset color.

The first functional layer may have a single layer or a multi-layer structure. As an example, in the case where the first functional layer includes a polymer material, the first functional layer may include a hole transport layer (HTL), which has a single-layered structure, and may include polyethylene dihydroxythiophene (PEDOT: poly-(3,4)-ethylene-dihydroxy thiophene), polyaniline (PANI: polyaniline), or similar. In the case where the first functional layer includes a low-molecular weight material, the first functional layer may include a hole injection layer (HIL) and an HTL.

The second functional layer may include an electron transport layer (ETL) and/or an electron injection layer (EIL).

The intermediate layer 222 may be modified in various ways. As an example, the intermediate layer 222 may include a first stack including the emission layer and the functional layer, a second stack including the emission layer and the functional layer, and a charge generation layer between the first stack and the second stack. The charge generation layer may include a negative charge generation layer and a positive charge generation layer. The light-emission efficiency of a tandem type light-emitting diode LED including the plurality of emission layers, may be further enhanced with inclusion the negative charge generation layer and the positive charge generation layer.

The negative charge generation layer may be an n-type charge generation layer. The negative charge generation layer may supply electrons. The negative charge generation layer may include hosts and dopants. The host may include an organic material. The dopant may include a metal material which may cause the negative charge generation layer to have negative charge carriers such as electrons when doped into the host. The positive charge generation layer may be a p-type charge generation layer. The positive charge generation layer may supply hole-type charge carriers. The positive charge generation layer may include hosts and dopants. The host may include an organic material. The dopant may include a metal material which may cause the positive charge generation layer to have hole-type charge carriers when doped into the host.

Although it is shown in FIG. 7 that the intermediate layer 222 is patterned to correspond to the pixel electrode 221 and is isolated from other pixel electrodes of the plurality of pixel electrodes, the disclosure is not limited thereto. As an example, the emission layer included in the intermediate layer 222 may be patterned to correspond to the pixel electrode 221 and may be isolated, but layers other than the emission layer included in the intermediate layer 222 may be integrally formed over the plurality of pixel electrodes 221. However, various modifications may be made. The portions of the intermediate layer 222 corresponding to the plurality of convex portions 213 may have a curved shape in accordance with the shape of the upper surface of the pixel electrode 221.

The common electrode 223 disposed on the intermediate layer 222 may be a light-transmissive electrode or a semi-light-transmissive electrode. As an example, the common electrode 223 may include a metal thin film with a small work function including Li, Ca, Al, Ag, Mg, or a compound thereof (e.g., LiF). In addition, the common electrode 223 may further include a transparent conductive oxide (TCO) layer such as ITO, indium zinc oxide (IZO), ZnO, ZnO₂, In₂O₃, or similar, disposed on the metal thin film.

The common electrode 223 may be integrally formed as a single body over the entire surface of the display area DA to cover the display area DA and may be disposed on the intermediate layer 222 and the pixel-defining layer 215. That is, the common electrode 223 may be integrally formed to correspond to a plurality of organic light-emitting diodes. The plurality of organic light-emitting diodes may share the common electrode 223. A stack structure of the pixel electrode 221, the intermediate layer 222, and the common electrode 223 may correspond to the organic light-emitting diode. The portion of the common electrode 230 corresponding to the plurality of convex portions 213 may have a curved shape in accordance with the shape of the upper surface of the pixel electrode 221.

A capping layer (not shown) may be disposed on the common electrode 223. The capping layer may be a material chosen to improve the light output and/or tune the spectral characteristics of the organic light-emitting diode and may include, for example, lithium fluoride (LiF). The capping layer may be omitted.

The display element 220 such as the organic light-emitting diode may be covered by the thin-film encapsulation layer 300. When the capping layer is present, the thin-film encapsulation layer 300 may be disposed on the capping layer. The thin-film encapsulation layer 300 may include at least one organic encapsulation layer and at least one inorganic encapsulation layer. It is shown in FIG. 7 that the thin-film encapsulation layer 300 includes first and second inorganic encapsulation layers 310 and 330 and an organic encapsulation layer 320 between the first inorganic encapsulation layer 310 and the second organic encapsulation layer 330. The number of organic encapsulation layers, the number of inorganic encapsulation layers, and a stacking order are not limited to those described and may be varied.

The first and second inorganic encapsulation layers 310 and 330 may include at least one inorganic material chosen from among aluminum oxide, titanium oxide, tantalum oxide, hafnium oxide, zinc oxide, silicon oxide, silicon nitride, and silicon oxynitride. Each of the first and second inorganic encapsulation layers 310 and 330 may have a single-layered structure or a multi-layered structure. The organic encapsulation layer 320 may include a polymer-based material. The polymer-based material may include an acryl-based resin such as polymethylmethacrylate or poly acrylic acid, an epoxy-based resin, polyimide, and/or polyethylene. As an example, the organic encapsulation layer 320 may include acrylate.

The first inorganic encapsulation layer 310 and the second inorganic encapsulation layer 330 may include different materials. As an example, the first inorganic encapsulation layer 310 may include silicon oxynitride, and the second inorganic encapsulation layer 330 may include silicon nitride.

The first inorganic encapsulation layer 310 may have a curved portion in accordance with the shape of the common electrode 223. The organic encapsulation layer 320 may have a substantially flat upper surface, and accordingly, the second inorganic encapsulation layer 330 may also have a substantially flat upper surface.

As described above, the pixel electrode 221 may be a reflective electrode. The emission layer included in the intermediate layer 222 may emit light that spreads in all directions rather than emitting light that is directed in a specific direction. Accordingly, to improve visibility not only in the front (+z direction) of the display panel 10 and the electronic apparatus 1, including the same, but also visibility in the lateral direction, an increase in the amount of light emitted in a direction at an angle of about 45° with respect to the front (+z direction) of the display panel 10 and the electronic apparatus 1 including the same may be provided.

As described above, in the display panel 10 and the electronic apparatus 1 including the same, because the plurality of convex portions 213 are present below the pixel electrode 221, the upper surface of the pixel electrode 221 includes the plurality of third convex surfaces. This may be understood as meaning that the upper surface of the reflective layer included in the pixel electrode 221 includes third convex surfaces. The direction of progression of reflected light emitted from the emission layer included in the intermediate layer 222, incident to the pixel electrode 221, and reflected by the pixel electrode 221 may be controlled through the shape of the upper surface of the pixel electrode 221, which is the reflective electrode. That is, due to the shape of the upper surface of the pixel electrode 221, which is the reflective electrode, the amount of light emitted in a direction at an angle of about 45° with respect to the front (+z direction) of the display panel 10 and the electronic apparatus 1 including the same may be increased. As a result, not only visibility in the front direction (+z direction) of the display panel 10 and the electronic apparatus 1, including the same, but also visibility in the lateral direction may be increased.

For reference, the reason the upper surface of the pixel electrode 221, which is the reflective electrode, has the above-described shape is because the plurality of convex portions 213 are disposed thereunder. However, in the display panel 10 and the electronic apparatus 1, including the same, according to an embodiment, because not only the plurality of convex portions 213 but also the convex insulating layer 214 covering the plurality of convex portions 213 is disposed between the plurality of convex portions 213 and the pixel electrode 221, an effect of visibility improvement in the lateral direction may be further increased.

To increase the visibility improvement in the lateral direction, an interval between the plurality of convex portions 213 may be reduced as much as possible. However, when forming the plurality of convex portions 213 apart from each other by forming an organic material layer and patterning the same, it is not easy to reduce an interval between the plurality of convex portions 213. This is a fundamental problem that occurs when patterning a layer including an organic material, unlike a layer including an inorganic material. Forming the plurality of convex portions by forming an inorganic material layer and patterning the same may be used to account for this problem. However, in case of patterning a layer including an inorganic material, another problem arises, it is very difficult to form the upper surface of each of the plurality of convex portions apart from each other such that the upper surface has a smooth curved surface like the surface of a convex lens. Thus, according to aspects of the present disclosure a combination of organic and inorganic convex surfaces may be provided to resolve these problems.

In the display panel 10 and the electronic apparatus 1 including the same according to an embodiment, because the plurality of convex portions 213 apart from each other are formed by forming an organic material layer and patterning the same, the upper surface of each of the plurality of convex portions 213 apart from each other may have the first convex surface, which is a smooth curved surface like the surface of a convex lens. In addition, the convex insulating layer 214 includes an inorganic material and covers the plurality of convex portions 213, the upper surface of the convex insulating layer 214 may therefore include the plurality of second convex surfaces corresponding to the plurality of convex portions 213. Because the convex insulating layer 214 includes an inorganic material, an interval between the plurality of second convex surfaces may be reduced compared to an interval between the plurality of convex portions 213 formed with an organic material. Accordingly, through this structure, the display panel 10 in which an effect of visibility in the lateral direction may be increased even more, and the electronic apparatus 1 including the display panel 10 may be implemented.

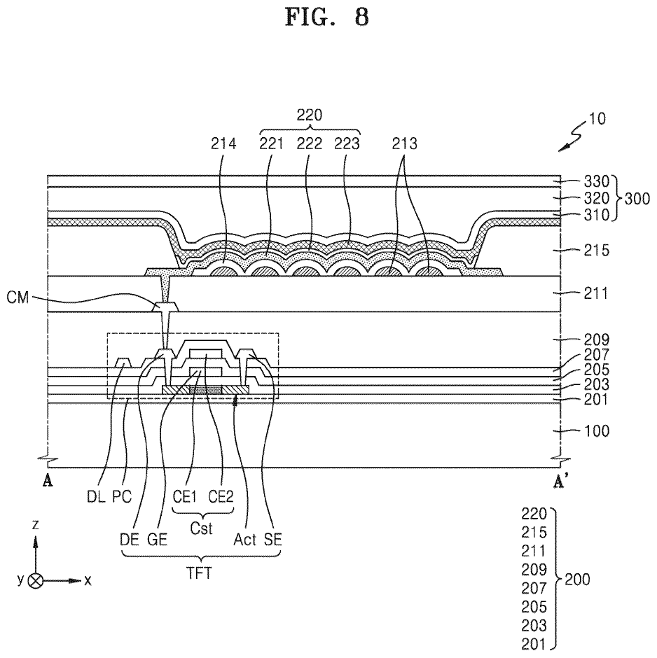

It is shown in FIG. 7 that the convex insulating layer 214 covers the plurality of convex portions 213. However, the disclosure is not limited thereto. As an example, as shown in FIG. 8, which is a schematic cross-sectional view of the display panel 10 according to an embodiment, the convex insulating layer 214 may extend to the outside of the plurality of convex portions 213. In this case, a portion of the upper surface of the convex insulating layer 214 may have a substantially flat shape.

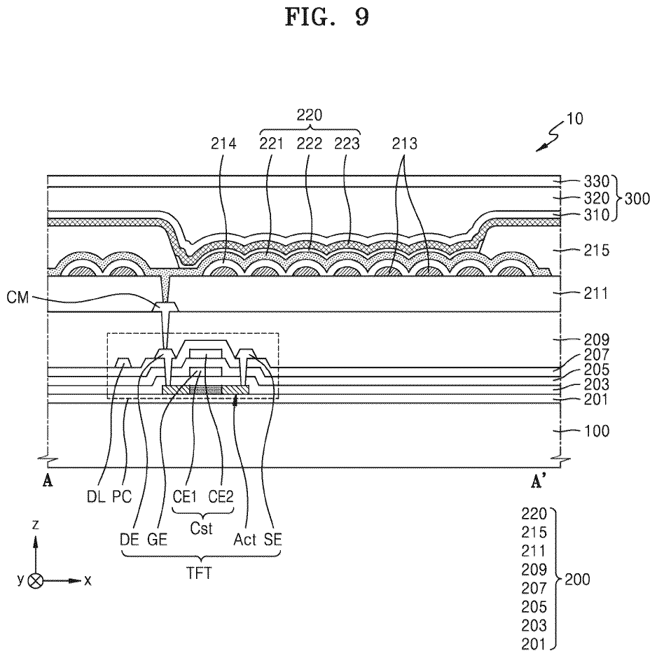

As shown in FIGS. 7 and 8, the plurality of convex portions 213 may be located in the opening of the pixel-defining layer 215. That is, the plurality of convex portions 213 may be located in the opening of the pixel-defining layer 215 in a plan view. However, the disclosure is not limited thereto, and some of the plurality of convex portions 213 may be located outside of the opening of the pixel-defining layer 215 in a plan view. As shown in FIG. 9, which is a schematic cross-sectional view of the display panel 10 according to aspects of the present disclosure, some of the plurality of convex portions 213 may be located outside of the opening of the pixel-defining layer 215.

Some of light emitted from the emission layer included in the intermediate layer 222 may travel along the interface between layers without progressing to the front (+z direction) due to a wave guide effect. As an example, light may travel along the interface between the pixel electrode 221 and the pixel-defining layer 215 or the interface between the second organic insulating layer 211 and the pixel-defining layer 215. In the display panel 10 according to the present embodiment, some of the plurality of convex portions 213 are located outside of the opening of the pixel-defining layer 215 as described above. Accordingly, a light path may be changed such that at least a portion of light traveling outside of the opening of the pixel-defining layer 215 along the interface between the pixel electrode 221 and the pixel-defining layer 215 due to a wave guide effect progresses to the front (+z direction). As a result, brightness in the front (+z direction) of the display panel 10 and the electronic apparatus 1 including the display panel 10 is increased, and thus, visibility of images displayed in the display area may be increased.

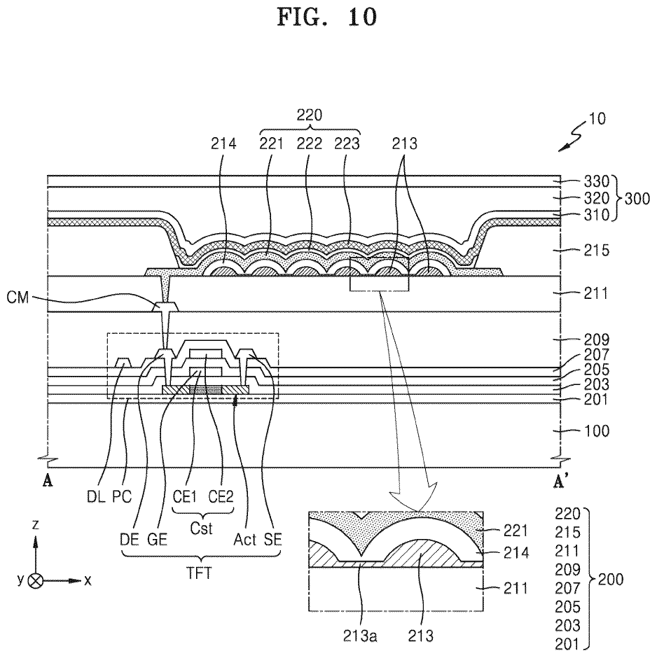

FIG. 10 is a schematic cross-sectional view of the display panel 10 according to aspects of the present disclosure. As described above, the plurality of convex portions 213 may be apart from each other. The display panel 10 according to the present embodiment and the electronic apparatus 1, including the same, may further include a connector region 213a. The connector region 213a may be located between the plurality of convex portions 213 and may connect the plurality of convex portions 213 to each other. As an example, in a plan view, the connector regions 213a may have a mesh-like structure and connect the plurality of convex portions 213 to each other. The connector region 213a may have a thickness less than a maximum height of each of the plurality of convex portions 213. In addition, the plurality of convex portions 213 and the connector regions 213a may be integrally formed as a single body.

To form the plurality of convex portions 213 as described above, the base organic insulating layer including an organic insulating material may be formed on the second organic insulating layer 211, and the base organic insulating layer may be patterned using a photoresist and the like with an etchant selected for the base organic insulating layer. In this case, a portion of the base organic insulating layer may remain between the plurality of convex portions 213, and this remaining portion may be the connector region 213a described above. The connector regions 213a may not be present between the plurality of convex portions 213, but an interval between the plurality of convex portions 213 may be very narrow depending on the size and the resolution of the display panel 10 and the electronic apparatus 1, including the same. In this case, the shape of the plurality of convex portions 213 may be transformed during the process of forming the plurality of convex portions 213 by allowing the connector regions 213a to be present between the plurality of convex portions 213.

FIG. 11 is a schematic plan view of a portion of the display panel 10 according to an embodiment. For convenience, FIG. 11 shows only pixel electrodes 221R, 221G, and 221B, and the plurality of convex portions 213.

As shown in FIG. 11, blue pixel electrodes 221B and red pixel electrodes 221R may be located in alternating order in a first direction (x axis direction) in a first row, and green pixel electrodes 221G may be located in the first direction (x axis direction) in a second row. Alternatively, the blue pixel electrodes 221B and the red pixel electrodes 221R may be located in alternative order in a second direction (y axis direction) in one column, and the green pixel electrodes 221G may be located in the second direction (y axis direction) in the next column.

In FIG. 11, a circular region is indicated by a dotted line on each of the pixel electrodes 221R, 221G, and 221B, and this circular region may represent the opening of the pixel-defining layer 215. The size of the opening of the pixel-defining layer 215 may be different depending on the pixel electrodes 221R, 221G, and 221B. As an example, in a plan view, the area of the opening of the pixel-defining layer 215 corresponding to the blue pixel electrode 221B may be largest, and the area of the opening of the pixel-defining layer 215 corresponding to the green pixel electrode 221G may be smallest. However, the disclosure is not limited thereto and may be modified in various ways.

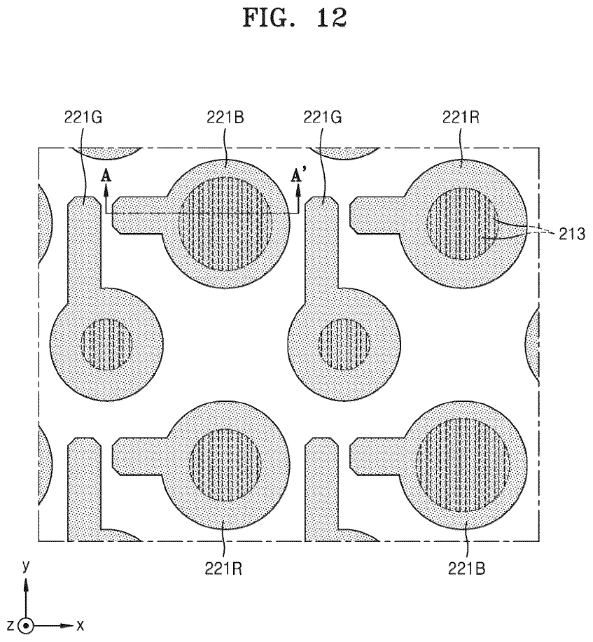

As described with reference to FIG. 7 and the like, and as shown in FIG. 11, the plurality of convex portions 213 may be located inside the opening of the pixel-defining layer 215. As described above with reference to FIG. 9, some of the plurality of convex portions 213 may be located outside of the opening of the pixel-defining layer 215. As shown in FIG. 11, each of the plurality of convex portions 213 may be shown to have a circular shape in a plan view. The disclosure is not limited thereto, and as shown in FIG. 12, which is a schematic plan view of a portion of the display panel 10 according to an embodiment, each of the plurality of convex portions 213 may be shown to have a shape extending in one direction (e.g., y axis direction, which is the second direction) in a plan view.

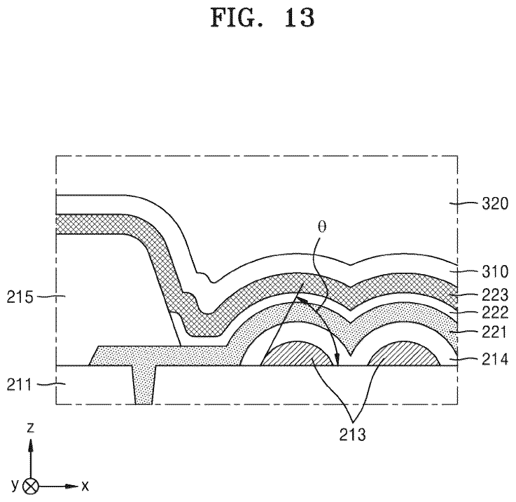

FIG. 13 is a schematic cross-sectional view of a portion of the display panel 10 according to aspects of the present disclosure and is an view of a portion of the display panel 10 of FIG. 7. As shown in FIG. 13, a taper angle θ may be defined for each of the plurality of convex portions 213. The taper angle θ may be defined as an angle between a line tangent to the convex surface of each of the plurality of convex portions 213, extended from the edge of each of the plurality of convex portions 213 and the upper surface of the second organic insulating layer 211. Considering only the shape of an angle, the taper angle θ may be defined in the same way as a contact angle of a liquid dotted on a solid surface, for example.

The taper angle θ at the edge of each of the plurality of convex portions 213 defined as described above and may be about 25° to about 35°. When the taper angle θ is less than 25°, the degree of convexity of each of the plurality of convex portions 213 decreases, and a brightness increasing effect on the lateral surface having a viewing angle of approximately 45° with respect to a direction perpendicular to the substrate 100 (z axis direction) may be drastically reduced. Accordingly, it may be desirable that the taper angle θ at the edge of each of the plurality of convex portions 213 is 25° or more. When the taper angle θ is greater than 35°, the degree of convexity of each of the plurality of convex portions 213 excessively increases, and brightness in the front (+z direction) of the display panel 10 may decrease. Accordingly, it may be desirable that the taper angle θ at the edge of each of the plurality of convex portions 213 is 35° or less.

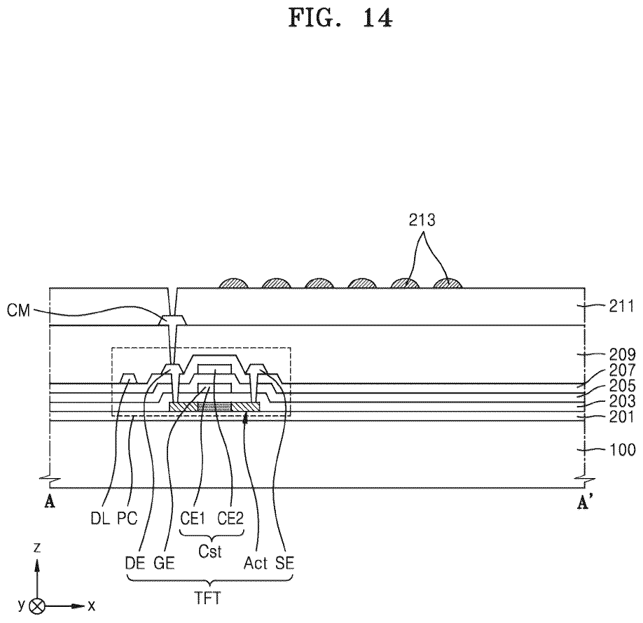

FIGS. 14 to 17 are schematic cross-sectional views showing operations of manufacturing the display panel 10 according to an embodiment. As shown in FIG. 14, at least a portion of the contact metal layer CM may be exposed by forming the second organic insulating layer 211 covering the contact metal layer CM and forming a contact hole in the second organic insulating layer 211. Subsequently, as shown in FIG. 14, the plurality of convex portions 213 may be formed on the second organic insulating layer 211 by forming the base organic insulating layer including the organic insulating material on the second organic insulating layer 211, and patterning the base organic insulating layer using a photoresist and the like with etchant selected for the base organic insulating material. The base organic insulating layer may fill a contact hole of the second organic insulating layer 211, and a portion of the base organic insulating layer located in the contact hole may be removed while the base organic insulating layer is patterned.

Alternatively, as shown in FIG. 14, the plurality of convex portions 213 may be formed on the second organic insulating layer 211 by forming the second organic insulating layer 211 covering the contact metal layer CM and the like, forming the base organic insulating layer including the organic insulating material on the second organic insulating layer 211, and then patterning the base organic insulating layer using a photoresist and the like with etchant selected for the base organic insulating material. In this case, a contact hole exposing at least a portion of the contact metal layer CM may be formed in the second organic insulating layer 211 by simultaneously removing a portion of the second organic insulating layer 211 and a portion of the base organic insulating layer on the contact metal layer CM when patterning the base organic insulating layer. For reference, a half-tone mask may be used during the process of exposing a photoresist.

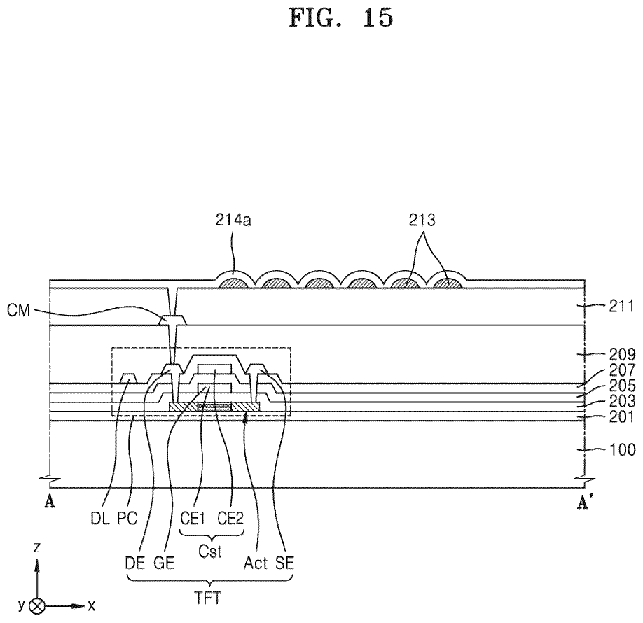

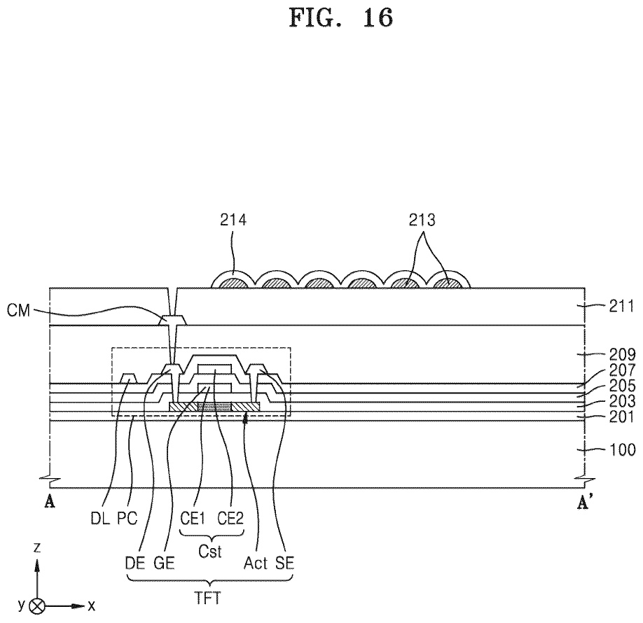

Subsequently, the convex insulating layer 214 as shown in FIG. 16 may be formed by creating a base layer 214a including an inorganic insulating material covering the plurality of convex portions 213 and then patterning the base layer 214a as shown in FIG. 15. The base layer 214a may fill a contact hole of the second organic insulating layer 211 when forming the base layer 214a. A portion of the base layer 214a located in the contact hole may be removed when patterning the base layer 214a.

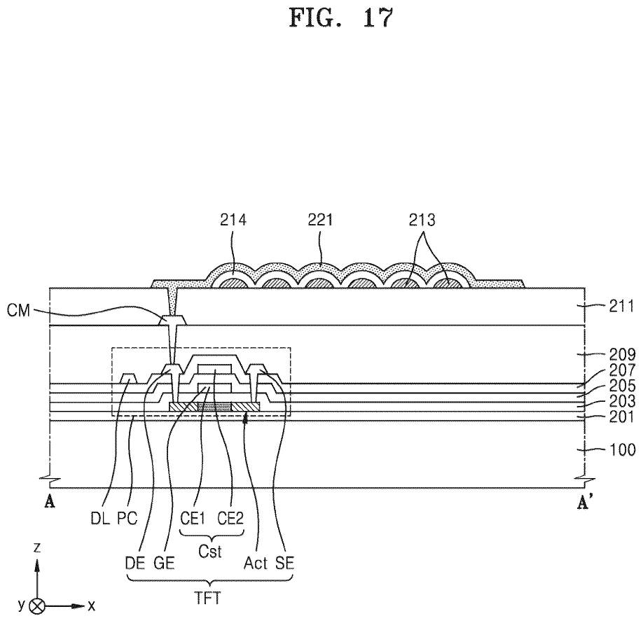

Then, the pixel electrode 221 which includes a portion located on the convex insulating layer 214 and which is in contact with the contact metal layer CM through a contact hole as shown in FIG. 17 may be formed by depositing a layer for forming a pixel electrode on the second organic insulating layer 211 and the convex insulating layer 214, and then patterning the same. After forming the pixel electrode 221, the process of forming the pixel-defining layer 215, the intermediate layer 222, the common electrode 223, and the like may be performed to manufacture the display panel 10 and the electronic apparatus 1 including the display panel 10.

Although, up to this point, the structure of the display panel 10 has been mainly described, the disclosure is not limited thereto. The electronic apparatus 1, including the display panel 10 also falls within the scope of the disclosure.

According to an embodiment, the display panel in which brightness reduction in the lateral direction is reduced and the electronic apparatus including the display panel may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a planarization layer;
a plurality of convex portions disposed on the planarization layer and spaced apart from each other, wherein an upper surface of each of the plurality of convex portions includes a first convex surface;
a convex insulating layer covering the plurality of convex portions and including an upper surface that includes a plurality of second convex surfaces corresponding to the plurality of convex portions; and
a pixel electrode disposed on the convex insulating layer and including an upper surface that includes a plurality of third convex surfaces corresponding to the plurality of second convex surfaces.

2. The display panel of claim 1, wherein the plurality of convex portions include an organic material.

3. The display panel of claim 1, wherein the convex insulating layer includes an inorganic material.

4. The display panel of claim 1, wherein the pixel electrode extends outside of the convex insulating layer and is electrically connected to a thin-film transistor disposed below the planarization layer through a contact hole in the planarization layer.

5. The display panel of claim 1, further comprising a pixel-defining layer including an opening around a central portion of the pixel electrode and disposed on the planarization layer to cover an edge of the pixel electrode.

6. The display panel of claim 5, wherein, in a plan view, the plurality of convex portions are located in the opening.

7. The display panel of claim 5, wherein, in a plan view, some of the plurality of convex portions are located outside the opening.

8. The display panel of claim 1, further comprising a connector region located between each convex portion in the plurality of convex portions, connecting the plurality of convex portions to each other, and having a thickness less than a maximum height of each of the plurality of convex portions.

9. The display panel of claim 8, wherein the plurality of convex portions and the connector region are integral as a single body.

10. The display panel of claim 1, wherein a taper angle at an edge of each of the plurality of convex portions with respect to an upper surface of the planarization layer is about 25° to about 35°.

11. The display panel of claim 1, wherein, in a plan view, each of the plurality of convex portions has a circular shape.

12. The display panel of claim 11, wherein a diameter of the circular shape is about 2 μm to about 10 μm.

13. The display panel of claim 11, wherein a thickness of the convex insulating layer is about 0.5 μm to about 2 μm.

14. The display panel of claim 1, wherein, in a plan view, each of the plurality of convex portions has a shape extending in one direction.

15. The display panel of claim 1, wherein, in a plan view, an area of each of the plurality of second convex surfaces is greater than an area of the first convex surface.

16. An electronic apparatus comprising:
one or more processors; and
a display panel controlled by the one or more processors,
wherein the display panel includes:
a planarization layer;
a plurality of convex portions disposed on the planarization layer and spaced apart from each other, wherein an upper surface of each of the plurality of convex portions includes a first convex surface;
a convex insulating layer covering the plurality of convex portions and including an upper surface that includes a plurality of second convex surfaces corresponding to the plurality of convex portions; and
a pixel electrode disposed on the convex insulating layer and including an upper surface that includes a plurality of third convex surfaces corresponding to the plurality of second convex surfaces.

17. The electronic apparatus of claim 16, wherein the plurality of convex portions include an organic material.

18. The electronic apparatus of claim 16, wherein the convex insulating layer includes an inorganic material.

19. The electronic apparatus of claim 16, further comprising a pixel-defining layer including an opening around a central portion of the pixel electrode and disposed on the planarization layer to cover an edge of the pixel electrode.

20. The electronic apparatus of claim 19, wherein, in a plan view, the plurality of convex portions are located in the opening.
